(19) United States
(12) Patent Application Publication
(10) Pub. No.: US 2024/0324193 A1
(43) Pub. Date: Sep. 26, 2024

(54) SEMICONDUCTOR DEVICE

(71) Applicant: SAMSUNG ELECTRONICS CO., LTD., Suwon-si (KR)

(72) Inventors: MinKyung KIM, Suwon-si (KR); Hakseon Kim, Suwon-si (KR); Sunggil Kim, Suwon-si (KR); Jumi Bak, Suwon-si (KR); Kang-Oh Yun, Suwon-si (KR); Dongjin Lee, Suwon-si (KR); Sohyun Lee, Suwon-si (KR); Junhee Lim, Suwon-si (KR)

(21) Appl. No.: 18/515,449

(22) Filed: Nov. 21, 2023

(30) Foreign Application Priority Data
Mar. 23, 2023 (KR) 10-2023-0038000

(51) Int. Cl. H10B 41/35; H01L 23/528; H01L 25/065; H10B 41/10; H10B 41/27; H10B 43/10; H10B 43/27; H10B 43/35; H10B 80/00

(52) U.S. Cl. CPC H10B 41/35; H01L 23/5283; H01L 25/0652; H10B 41/10; H10B 41/27; H10B 43/10; H10B 43/27; H10B 43/35; H10B 80/00; H01L 2225/06524

(57) ABSTRACT

A semiconductor device includes a substrate, a doped region on the substrate, the doped region including impurities of a first conductivity type at a first concentration, a gate structure on the substrate, and a first contact electrically connected to the doped region, the first contact including a first portion, a second portion on the first portion, and a third portion on the second portion, the first portion and the second portion including poly silicon, the third portion including at least one metallic material, and the second portion including impurities of the first conductivity type at a second concentration higher than the first concentration.

### CROSS-REFERENCE TO RELATED APPLICATIONS

This U.S. non-provisional patent application claims priority under 35 U.S.C. § 119 to Korean Patent Application No. 10-2023-0038000, filed on Mar. 23, 2023, in the Korean Intellectual Property Office, the entire contents of which are hereby incorporated by reference.

### BACKGROUND

### 1. Field

The present disclosure relates to a semiconductor device, and in particular, to a semiconductor device including a transistor.

### 2. Description of the Related Art

Due to their small-size, multifunctionality, and/or low-cost characteristics, semiconductor devices are being esteemed as important elements in the electronics industry. The semiconductor devices are classified into semiconductor memory devices for storing data, semiconductor logic devices for processing data, and hybrid semiconductor devices including both of memory and logic elements.

With the recent trend of high speed and low power consumption of electronic devices, semiconductor devices in the electronic devices are also required to have high operating speeds and/or low operating voltages, and in order to satisfy this requirement, it is necessary to increase an integration density of the semiconductor device. However, as the integration density of the semiconductor device increases, the semiconductor device may suffer from deterioration in electrical characteristics and production yield. Accordingly, many studies are being conducted to improve the electrical characteristics and production yield of the semiconductor device.

### SUMMARY

According to an embodiment, a semiconductor device may include a substrate, a doped region on the substrate, a gate structure on the substrate, and a first contact electrically connected to the doped region. The first contact may include a first portion, a second portion on the first portion, and a third portion on the second portion. The first and second portions of the first contact may include poly silicon, and the third portion of the first contact may include at least one metallic material. The doped region may contain impurities of a first conductivity type at a first concentration, and the second portion of the first contact may contain impurities of the first conductivity type at a second concentration. The first concentration may be lower than the second concentration.

According to an embodiment, a semiconductor device may include a substrate, a doped region on the substrate, a gate structure on the substrate, an epitaxial pattern on the doped region, and a contact on the epitaxial pattern. The epitaxial pattern may include a first inclined surface, a second inclined surface, a top surface between the first and second inclined surfaces, a first side surface connected to the first inclined surface, and a second side surface connected to the second inclined surface. The first side surface of the epitaxial pattern may be in contact with a side surface of the gate structure.

According to an embodiment, a semiconductor device may include a substrate, an isolation region on the substrate, a device isolation layer on the isolation region, a doped region on the substrate, a gate structure on the substrate, an insulating structure covering the gate structure, and a contact electrically connected to the doped region. The contact may include a first portion, a second portion on the first portion, and a third portion on the second portion. The first and second portions of the contact may include poly silicon, and the third portion of the contact may include at least one of metallic materials. The doped region may contain impurities of a first conductivity type, and the second portion of the contact may contain impurities of the first conductivity type. The isolation region may contain impurities, which are of a second conductivity type different from the first conductivity type.

### BRIEF DESCRIPTION OF THE DRAWINGS

Features will become apparent to those of skill in the art by describing in detail exemplary embodiments with reference to the attached drawings, in which:

FIG. 1A is a plan view of a semiconductor device according to an embodiment.

FIG. 1B is a sectional view taken along line A1-A1′ of FIG. 1A.

FIGS. 2A, 2B, 2C, 2D, 2E, and 2F are sectional views of stages in a method of fabricating the semiconductor device of FIGS. 1A and 1B.

FIG. 3A is a plan view of a semiconductor device according to an embodiment.

FIG. 3B is a sectional view taken along line A2-A2′ of FIG. 3A.

FIG. 4 is a sectional view of a semiconductor device according to an embodiment.

FIGS. 5A, 5B, 5C, 5D, 5E, 5F, 5G, and 5H are sectional views of stages in a method of fabricating the semiconductor device of FIG. 4.

FIG. 6 is a sectional view of stages in a method of fabricating the semiconductor device of FIG. 4.

FIG. 7A is a schematic diagram of an electronic system including a semiconductor device according to an embodiment.

FIG. 7B is a perspective view schematically illustrating an electronic system including a semiconductor device according to an embodiment.

FIGS. 7C and 7D are sectional views, each of which schematically illustrates a semiconductor package according to an embodiment.

FIG. 8A is a plan view of a semiconductor device according to an embodiment.

FIG. 8B is a sectional view taken along line A3-A3′ of FIG. 8A.

### DETAILED DESCRIPTION

Example embodiments will now be described more fully with reference to the accompanying drawings, in which example embodiments are shown.

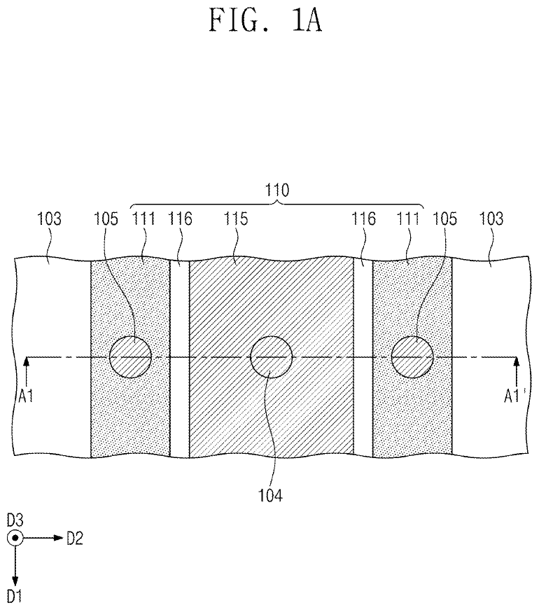

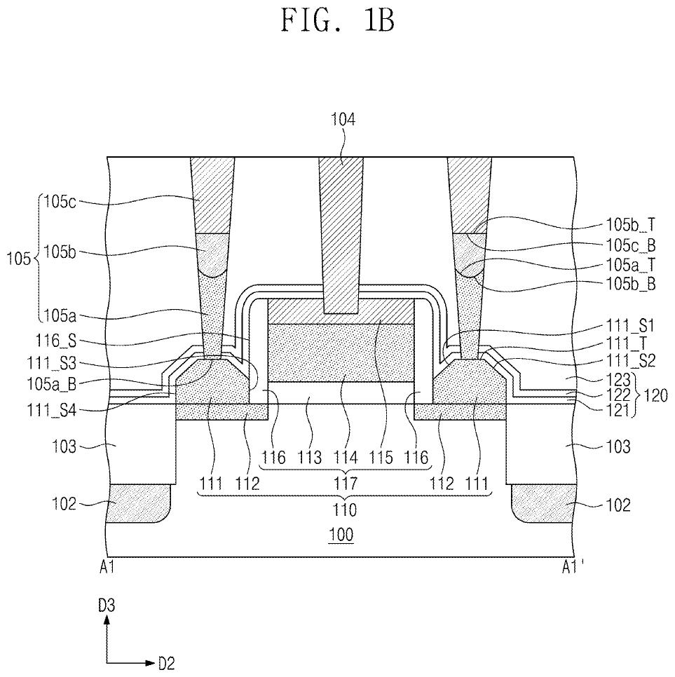

FIG. 1A is a plan view of a semiconductor device according to an embodiment. FIG. 1B is a sectional view taken along line A1-A1′ of FIG. 1A.

Referring to FIGS. 1A and 1B, a semiconductor device may include a substrate 100. The substrate 100 may be a plate-shaped structure that is extended parallel to a plane defined by a first direction D1 and a second direction D2. The first and second directions D1 and D2 may not be parallel to each other. In an embodiment, the first and second directions D1 and D2 may be two different horizontal directions, which are orthogonal to each other. In an embodiment, the substrate 100 may be a semiconductor substrate. As an example, the substrate 100 may be formed of or include silicon, germanium, silicon-germanium, GaP, or GaAs. In an embodiment, the substrate 100 may be a silicon-on-insulator (SOI) substrate or a germanium-on-insulator (GOI) substrate.

Isolation regions 102 may be provided on the substrate 100. The isolation region 102 may be formed by doping the substrate 100 with impurities. The isolation region 102 may contain impurities of a first conductivity type. In an embodiment, the first conductivity type may be a p-type, and the isolation region 102 may contain boron atoms.

Device isolation layers 103 may be provided on the substrate 100. The device isolation layer 103 may be provided on the isolation region 102. The device isolation layer 103 may be overlapped with the isolation region 102 in a third direction D3. The third direction D3 may not be parallel to the first and second directions D1 and D2. As an example, the third direction D3 may be a vertical direction orthogonal to the first and second directions D1 and D2. The device isolation layer 103 may be formed of or include an insulating material.

A transistor 110 may be provided on the substrate 100. The transistor 110 may be provided between the device isolation layers 103. The transistor 110 may be provided between the isolation regions 102. The transistor 110 may include doped regions 112, epitaxial patterns 111, and a gate structure 117.

The doped region 112 may be formed by doping the substrate 100 with impurities. The doped region 112 may contain impurities of a second conductivity type. For example, the second conductivity type may be an n-type, and the doped region 112 may contain phosphorus atoms. In an embodiment, the first conductivity type may be an n-type, and the second conductivity type may be a p-type. The doped region 112 may be a source/drain region of the transistor 110. A portion of the substrate 100 adjacent to the doped region 112 may contain impurities of the first conductivity type.

The epitaxial pattern 111 may be provided on the doped region 112. The epitaxial pattern 111 may be formed through a selective epitaxial growth process. The epitaxial pattern 111 may be formed of or include a single crystalline semiconductor material. In an embodiment, the epitaxial pattern 111 may be formed of or include single crystalline silicon. The epitaxial pattern 111 may contain impurities of the second conductivity type.

The gate structure 117 may be disposed between the epitaxial patterns 111. The gate structure 117 may include a gate insulating layer 113 on the substrate 100, a first gate conductive layer 114 on the gate insulating layer 113, a second gate conductive layer 115 on the first gate conductive layer 114, and gate spacers 116 on side surfaces of the gate insulating layer 113, the first gate conductive layer 114, and the second gate conductive layer 115.

The gate insulating layer 113 may include an insulating material. In an embodiment, the gate insulating layer 113 may be formed of or include at least one of oxide materials. The first gate conductive layer 114 may include a conductive material. In an embodiment, the first gate conductive layer 114 may be formed of or include poly silicon. The second gate conductive layer 115 may include a conductive material. In an embodiment, the second gate conductive layer 115 may be formed of or include at least one of metallic materials, e.g., at least one of an elemental metal material, a compound metal material, etc. The gate spacer 116 may include an insulating material. In an embodiment, the gate spacer 116 may be formed of or include at least one of oxide materials.

As illustrated in FIG. 1B, the epitaxial pattern 111 may have a pentagonal vertical cross-section. That is, the epitaxial pattern 111 may include a top surface 111_T, a first inclined surface 111_S1 connected to the top surface 111_T, a second inclined surface 111_S2 connected to the top surface 111_T, a first side surface 111_S3 connected to the first inclined surface 111_S1, and a second side surface 111_S4 connected to the second inclined surface 111_S2.

In detail, the first and second inclined surfaces 111_S1 and 111_S2 of the epitaxial pattern 111 may be inclined at an angle, e.g., at an oblique angle with respect to the top surface 111_T. In an embodiment, the first and second inclined surfaces 111_S1 and 111_S2 of the epitaxial pattern 111 may be inclined at an angle with respect to a top surface of the substrate 100. The top surface 111_T of the epitaxial pattern 111 may be disposed between the first and second inclined surfaces 111_S1 and 111_S2 of the epitaxial pattern 111, e.g., the first and second inclined surfaces 111_S1 and 111_S2 may be symmetrical with respect to the top surface 111_T.

The first side surface 111_S3 of the epitaxial pattern 111 may be in contact (e.g., direct contact) with a side surface 116_S of the gate spacer 116. The first and second side surfaces 111_S3 and 111_S4 of the epitaxial pattern 111 may be parallel to the side surface 116_S of the gate spacer 116. The side surface 116_S of the gate spacer 116 may be a side surface of the gate structure 117. In an embodiment, the second side surface 111_S4 of the epitaxial pattern 111 may be inclined at an angle. As an example, the second side surface 111_S4 of the epitaxial pattern 111 may be inclined at an angle (e.g., an oblique angle) with respect to the top surface of the substrate 100.

A level of the top surface 111_T of the epitaxial pattern 111 may be higher than a level of a top surface of the gate insulating layer 113, e.g., relative to a bottom of the substrate 100. The level of the top surface 111_T of the epitaxial pattern 111 may be lower than a level of a top surface of the first gate conductive layer 114, e.g., relative to the bottom of the substrate 100.

An insulating structure 120 may be provided to cover the epitaxial patterns 111, the device isolation layers 103, and the gate structure 117. The insulating structure 120 may include a first insulating layer 121 covering the epitaxial patterns 111, the device isolation layers 103, and the gate structure 117, a second insulating layer 122 on the first insulating layer 121, and a third insulating layer 123 on the second insulating layer 122. A top surface of the second gate conductive layer 115 of the gate structure 117 may be in contact (e.g., direct contact) with the first insulating layer 121 of the insulating structure 120.

The first to third insulating layers 121, 122, and 123 may include at least one of insulating materials. As an example, the first and third insulating layers 121 and 123 may be formed of or include at least one of oxide materials, and the second insulating layer 122 may be formed of or include at least one of nitride materials.

First contacts 105 may be provided in the insulating structure 120. The first contact 105 may be electrically connected to the epitaxial pattern 111 and the doped region 112. The first contact 105 may be provided on (e.g., directly on) the top surface 111_T of the epitaxial pattern 111. The first contact 105 may be provided to penetrate the first insulating layer 121 and the second insulating layer 122.

The first contact 105 may include a first portion 105a on the top surface 111_T of the epitaxial pattern 111, a second portion 105b on the first portion 105a, and a third portion 105c on the second portion 105b, e.g., the second portion 105b may be between the first portion 105a and the third portion 105c. The first and second portions 105a and 105b of the first contact 105 may be formed of or include poly silicon. The third portion 105c of the first contact 105 may include at least one of metallic materials.

In an embodiment, the first and second portions 105a and 105b of the first contact 105 may be formed by a selective epitaxial growth process and may include a single crystalline semiconductor material. As an example, the first and second portions 105a and 105b of the first contact 105 may be formed of or include single crystalline silicon.

The first and second portions 105a and 105b of the first contact 105 may contain impurities of the second conductivity type. A concentration of the second conductivity type impurities in the doped region 112 may be a first concentration. A concentration of the second conductivity type impurities in the second portion 105b of the first contact 105 may be a second concentration. The first concentration of the doped region 112 may be lower than the second concentration of the second portion 105b of the first contact 105. A concentration of the second conductivity type impurities in the first portion 105a of the first contact 105 may be a third concentration. The third concentration of the first portion 105a of the first contact 105 may be lower than the second concentration of the second portion 105b of the first contact 105. A concentration of the second conductivity type impurities in the epitaxial pattern 111 may be a fourth concentration. The fourth concentration of the epitaxial pattern 111 may be lower than the second concentration of the second portion 105b of the first contact 105.

In an embodiment, the first portion 105a of the first contact 105 may not contain any impurity. As an example, the first portion 105a of the first contact 105 may be formed of or include of undoped poly silicon.

A bottom surface 105a_B of the first portion 105a of the first contact 105 may be in contact (e.g., direct contact) with the top surface 111_T of the epitaxial pattern 111. A level of the bottom surface 105a_B of the first portion 105a of the first contact 105 may be higher than the level of the top surface of the gate insulating layer 113, e.g., relative to the bottom of the substrate 100. The level of the bottom surface 105a B of the first portion 105a of the first contact 105 may be lower than the level of the top surface of the first gate conductive layer 114, e.g., relative to the bottom of the substrate 100.

A top surface 105a_T of the first portion 105a of the first contact 105 may have a curved shape. The top surface 105a_T of the first portion 105a of the first contact 105 may be concavely curved toward the epitaxial pattern 111 and the substrate 100. A level of the top surface 105a_T of the first portion 105a of the first contact 105 (e.g., a bottommost level of the top surface 105a_T) may be higher than a level of the top surface of the second gate conductive layer 115, e.g., relative to the bottom of the substrate 100.

A bottom surface 105b_B of the second portion 105b of the first contact 105 may have a curved shape. The bottom surface 105b_B of the second portion 105b of the first contact 105 may be convexly curved toward the epitaxial pattern 111 and the substrate 100. A level of the bottom surface 105b_B of the second portion 105b of the first contact 105 (e.g., a bottommost level of the bottom surface 105b_B) may be higher than the level of the top surface of the second gate conductive layer 115, e.g., relative to the bottom of the substrate 100.

A top surface 105b_T of the second portion 105b of the first contact 105 may be flat. A level of the top surface 105b_T of the second portion 105b of the first contact 105 may be higher than the level of the top surface of the second gate conductive layer 115, e.g., relative to the bottom of the substrate 100. The level of the top surface 105b_T of the second portion 105b of the first contact 105 may be higher than a level of a top surface of the gate structure 117, e.g., relative to the bottom of the substrate 100.

A bottom surface 105c_B of the third portion 105c of the first contact 105 may be flat. A level of the bottom surface 105c_B of the third portion 105c of the first contact 105 may be higher than the level of the top surface of the second gate conductive layer 115, e.g., relative to the bottom of the substrate 100.

A width of the first contact 105 may be smaller than a width of the epitaxial pattern 111, e.g., a maximal horizontal width of the first contact 105 may be smaller than a maximal horizontal width of the epitaxial pattern 111. In an embodiment, a width of the first contact 105 in the second direction D2 may be smaller than a width of the epitaxial pattern 111 in the second direction D2.

A second contact 104 may be provided on the gate structure 117. The second contact 104 may be in contact (e.g., direct contact) with the second gate conductive layer 115. The second contact 104 may include at least one of metallic materials.

According to an embodiment, since the semiconductor device includes the epitaxial pattern 111 and the first and second portions 105a and 105b of the first contact 105, a current path between the third portion 105c of the first contact 105, which contains a metallic material, and the gate structure 117 may be relatively long (e.g., since the first and second portions 105a and 105b increase a vertical distance in the third direction D3 between the metallic third portion 105c and the gate structure 117). In this case, the doped region 112 may have a relatively small size, and an integration density of the semiconductor device may be increased.

Further, according to an embodiment, since the semiconductor device includes the epitaxial pattern 111 and the first and second portions 105a and 105b of the first contact 105, the doped region 112 may have a relatively small thickness (e.g., measured from the bottom of the epitaxial pattern 111 in the third direction D3), and a distance between the isolation region 102 and the doped region 112 (e.g., in the third direction D3) may be relatively long. Thus, it may be possible to realize a semiconductor device with a relatively high breakdown voltage.

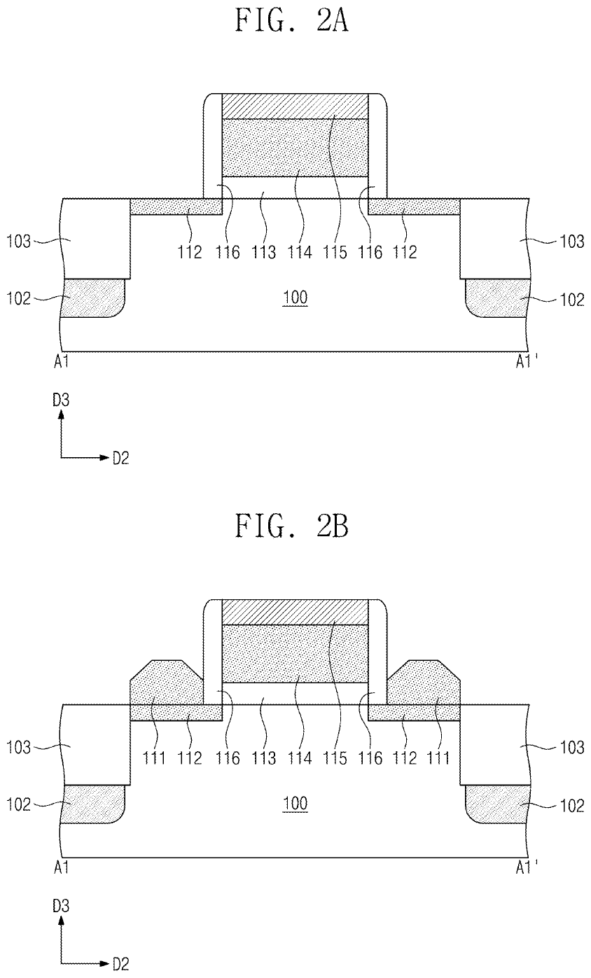

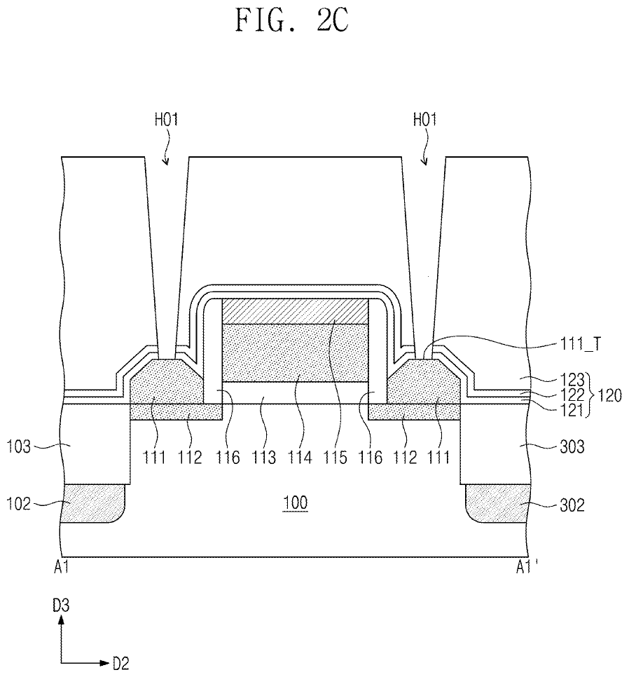

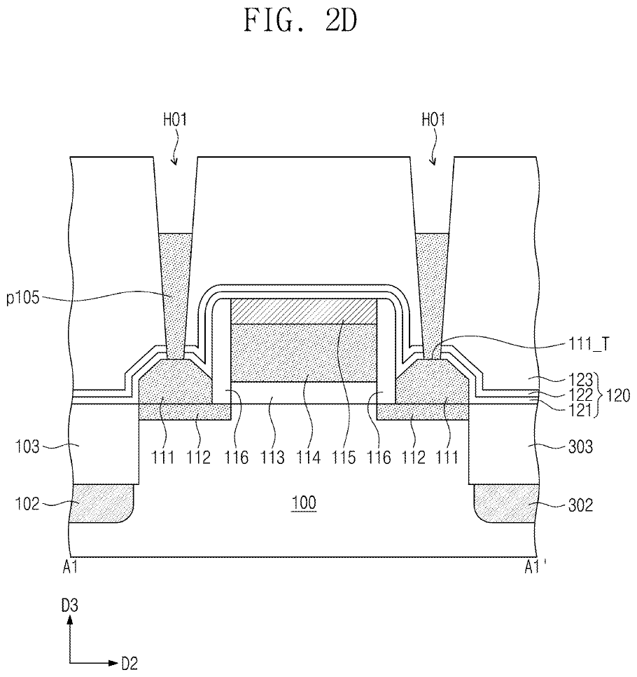

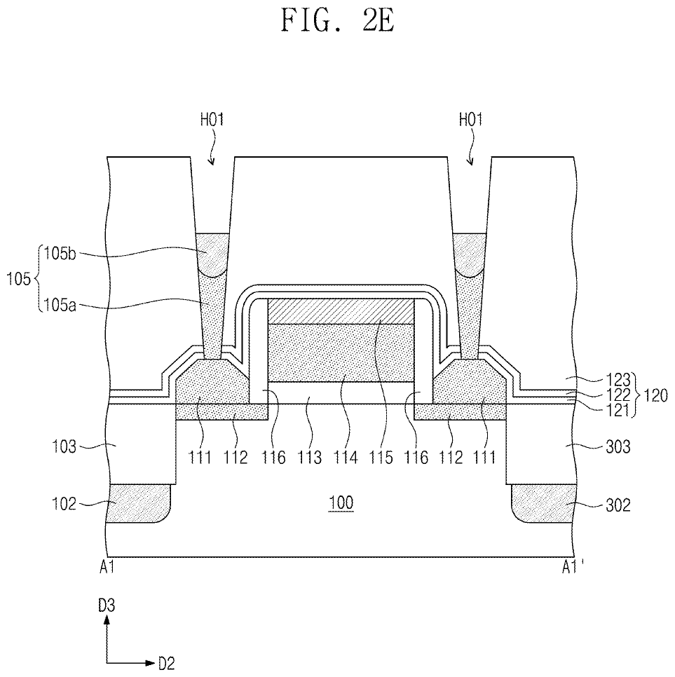

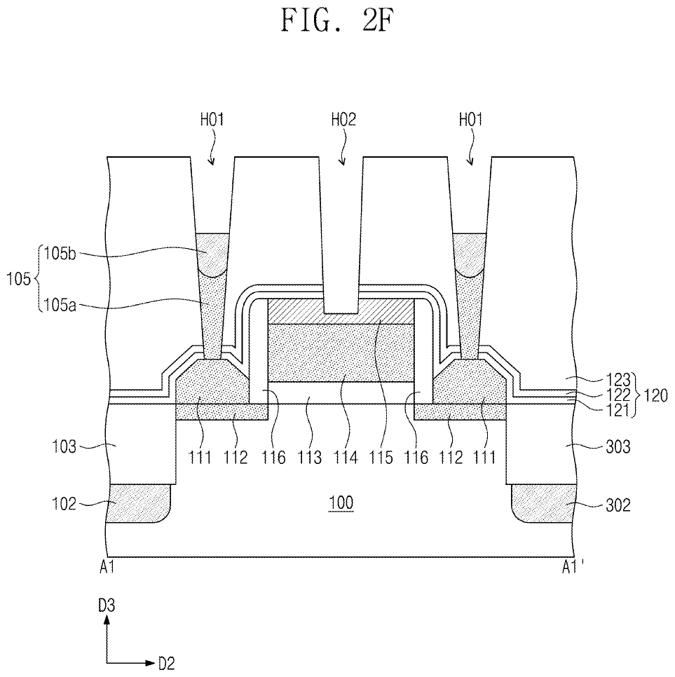

FIGS. 2A, 2B, 2C, 2D, 2E, and 2F are sectional views illustrating stages in a method of fabricating the semiconductor device of FIGS. 1A and 1B.

Referring to FIG. 2A, the isolation regions 102 and the device isolation layers 103 may be formed on the substrate 100. The gate insulating layer 113, the first gate conductive layer 114, and the second gate conductive layer 115 may be formed on the substrate 100. The doped regions 112 may be formed by doping the substrate 100 with impurities. The gate spacers 116 may be formed on the side surfaces of the gate insulating layer 113, the first gate conductive layer 114, and the second gate conductive layer 115.

Referring to FIG. 2B, the epitaxial patterns 111 may be formed. The epitaxial patterns 111 may be formed through a selective epitaxial growth process. In an embodiment, the epitaxial pattern 111 may be doped with impurities, after the formation of the epitaxial pattern 111 through the selective epitaxial growth process. In an embodiment, the impurity-doped epitaxial pattern 111 may be formed through the selective epitaxial growth process.

Referring to FIG. 2C, the insulating structure 120 may be formed. In an embodiment, the insulating structure 120 may be formed by sequentially forming the first insulating layer 121, the second insulating layer 122, and the third insulating layer 123.

First holes HO1 may be formed to penetrate the insulating structure 120. The first hole HO1 may be enclosed, e.g., completely surrounded in a top view, by the insulating structure 120. The first hole HO1 may be overlapped with the epitaxial pattern 111 and the doped region 112 in the third direction D3. The first hole HO1 may be formed to expose the top surface 111_T of the epitaxial pattern 111.

Referring to FIG. 2D, a preliminary contact layer p105 may be formed. The preliminary contact layer p105 may fill a lower portion of the first hole HO1. The preliminary contact layer p105 may be formed on the epitaxial pattern 111. The preliminary contact layer p105 may be formed of or include poly silicon. In an embodiment, the preliminary contact layer p105 may be doped with impurities of the second conductivity type.

In an embodiment, the preliminary contact layer p105 may be formed by a selective epitaxial growth process and may include a single crystalline semiconductor material. As an example, the preliminary contact layer p105 may be formed of or include single crystalline silicon.

Referring to FIG. 2E, the first and second portions 105a and 105b of the first contact 105 may be formed by doping an upper portion of the preliminary contact layer p105 with impurities of the second conductivity type. The upper portion of the preliminary contact layer p105 may be doped with the impurities of the second conductivity type such that an impurity concentration of the second portion 105b of the first contact 105 is higher than an impurity concentration of the first portion 105a of the first contact 105.

Referring to FIG. 2F, a second hole HO2 may be formed to penetrate the insulating structure 120. The second hole HO2 may be enclosed by the insulating structure 120. The second hole HO2 may be overlapped with the gate insulating layer 113, the first gate conductive layer 114, and the second gate conductive layer 115 in the third direction D3. The second hole HO2 may be formed to expose the second gate conductive layer 115.

Referring to FIG. 1B, the third portion 105c of the first contact 105 may be formed on the second portion 105b of the first contact 105. The third portion 105c of the first contact 105 may fill an upper portion of the first hole HO1. The second contact 104 may be formed to fill the second hole HO2. In an embodiment, the third portion 105c of the first contact 105 and the second contact 104 may be formed at the same time.

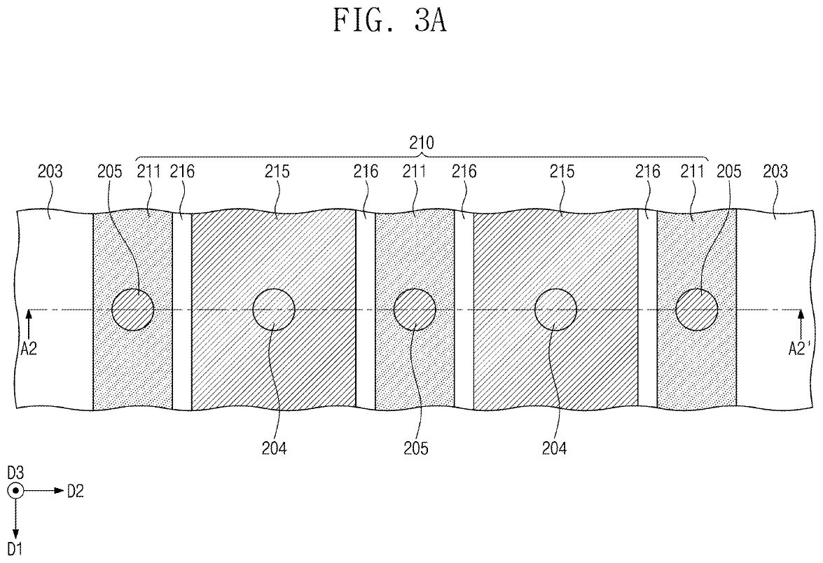

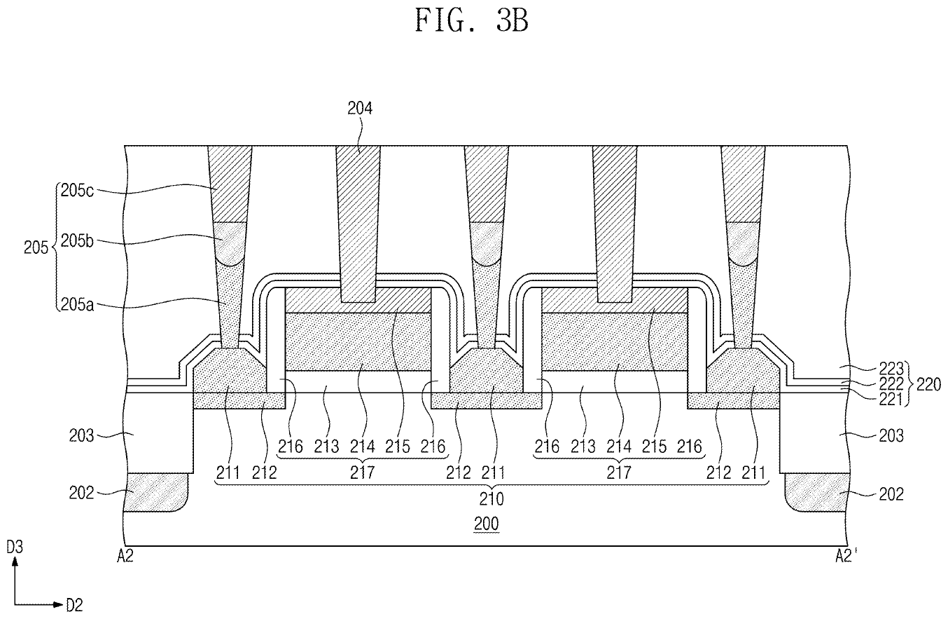

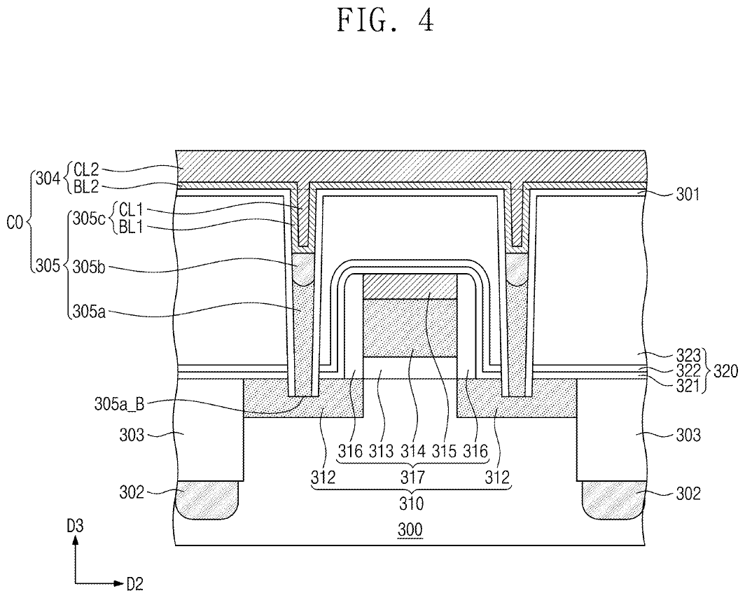

FIG. 3A is a plan view illustrating a semiconductor device according to an embodiment. FIG. 3B is a sectional view taken along line A2-A2′ of FIG. 3A.

Referring to FIGS. 3A and 3B, a semiconductor device may include a substrate 200. Isolation regions 202 and device isolation layers 203 may be provided on the substrate 200. A transistor 210 may be provided between the device isolation layers 203. The transistor 210 may include three doped regions 212, three epitaxial patterns 211, and two gate structures 217. Each of the gate structure 217 may be disposed between two epitaxial patterns 211.

The gate structure 217 may include a gate insulating layer 213, a first gate conductive layer 214, a second gate conductive layer 215, and a gate spacer 216. An insulating structure 220 may be provided to cover the transistor 210. The insulating structure 220 may include a first insulating layer 221, a second insulating layer 222, and a third insulating layer 223.

First contacts 205 may be provided. The first contact 205 may be provided on the epitaxial pattern 211. The first contact 205 may include a first portion 205a, a second portion 205b, and a third portion 205c. Second contacts 204 may be provided. The second contact 204 may be provided on the gate structure 217.

The first and second portions 205a and 205b of the first contact 205 may be formed of or include poly silicon. The third portion 205c of the first contact 205 may include at least one of metallic materials. The doped region 212, the epitaxial pattern 211, and the first and second portions 205a and 205b of the first contact 205 may be doped with impurities of the same conductivity type. An impurity concentration of the second portion 205b of the first contact 205 may be higher than impurity concentrations of the doped region 212, the epitaxial pattern 211, and the first portion 205a of the first contact 205.

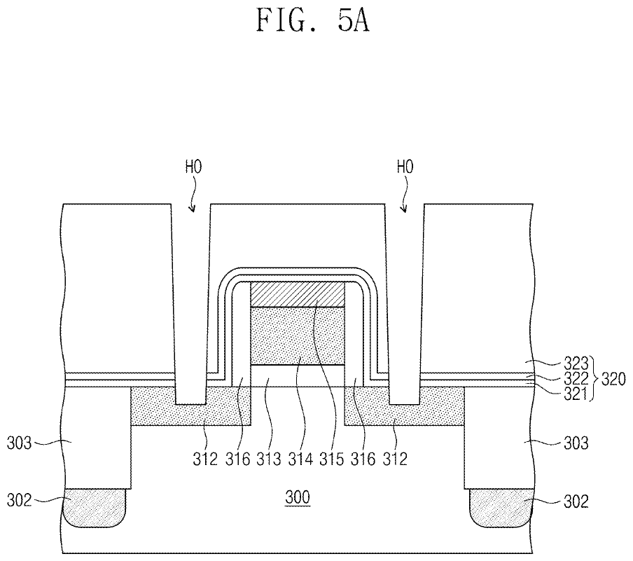

FIG. 4 is a sectional view illustrating a semiconductor device according to an embodiment.

Referring to FIG. 4, a semiconductor device may include a substrate 300. Isolation regions 302 and device isolation layers 303 may be provided on the substrate 300. A transistor 310 may be provided between the device isolation layers 303. The transistor 310 may include doped regions 312 and a gate structure 317.

The gate structure 317 may include a gate insulating layer 313, a first gate conductive layer 314, a second gate conductive layer 315, and a gate spacer 316. An insulating structure 320 may be provided to cover the transistor 310. The insulating structure 320 may include a first insulating layer 321, a second insulating layer 322, and a third insulating layer 323.

A conductive structure CO, which is electrically connected to the transistor 310, may be provided. The conductive structure CO may include contacts 305 and a connection layer 304. The contact 305 may be provided on the doped region 312. The contact 305 may include a first portion 305a, a second portion 305b, and a third portion 305c. The contacts 305 may be connected to each other by the connection layer 304. The connection layer 304 may be disposed at a level higher than the contacts 305, e.g., relative to a bottom of the substrate 300.

An intervening layer 301 may be provided between the insulating structure 320 and the conductive structure CO. The intervening layer 301 may include a first portion, which is disposed between the insulating structure 320 and the connection layer 304, and a second portion, which is provided to enclose the contact 305. The intervening layer 301 may include an insulating material. As an example, the intervening layer 301 may be formed of or include at least one of nitride materials.

The first and second portions 305a and 305b of the contact 305 may be formed of or include poly silicon. The third portion 305c of the contact 305 may include a first barrier layer BL1 on the second portion 305b of the contact 305 and a first conductive layer CL1 on the first barrier layer BL1. The first barrier layer BL1 and the first conductive layer CL1 may include at least one of metallic materials. The connection layer 304 may include a second barrier layer BL2 on the intervening layer 301 and a second conductive layer CL2 on the second barrier layer BL2. The second barrier layer BL2 and the second conductive layer CL2 may include at least one of metallic materials.

The first and second barrier layers BL1 and BL2 may be formed of or include the same material, e.g., may be integral and form a same layer. The first and second barrier layers BL1 and BL2 may be connected to each other without any interface therebetween, thereby forming a single object structure. The first and second conductive layers CL1 and CL2 may be formed of or include the same material, e.g., may be integral and form a same layer. The first and second conductive layers CL1 and CL2 may be connected to each other without any interface therebetween, thereby forming a single object structure.

A level of a bottom surface 305a_B of the first portion 305a of the contact 305 may be higher than a level of a bottom surface of the doped region 312 and may be lower than a level of a top surface of the doped region 312, e.g., relative to the bottom of the substrate 300. The doped region 312 and the first and second portions 305a and 305b of the contact 305 may be doped with impurities of the same conductivity type. An impurity concentration of the second portion 305b of the contact 305 may be higher than impurity concentrations of the doped region 312 and the first portion 305a of the contact 305. In an embodiment, a mean size of crystalline grains in the first and second portions 305a and 305b of the contact 305 may decrease as a vertical level is lowered.

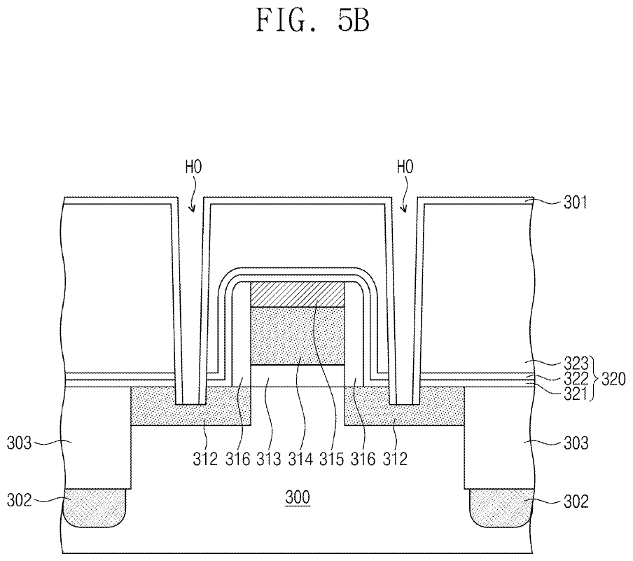

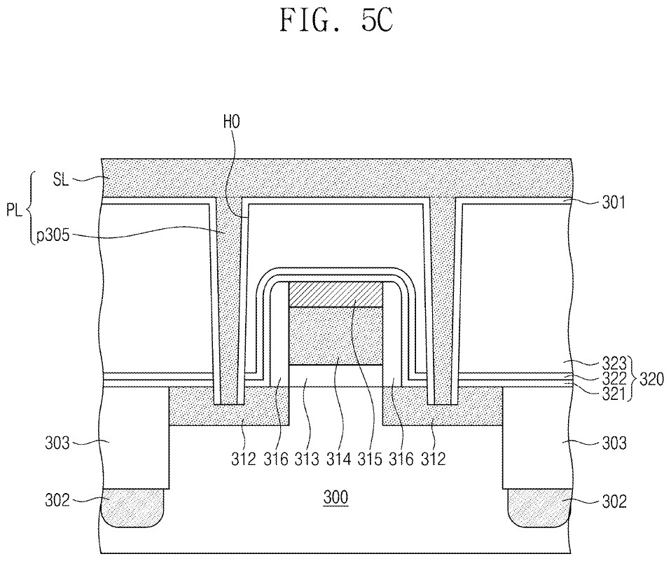

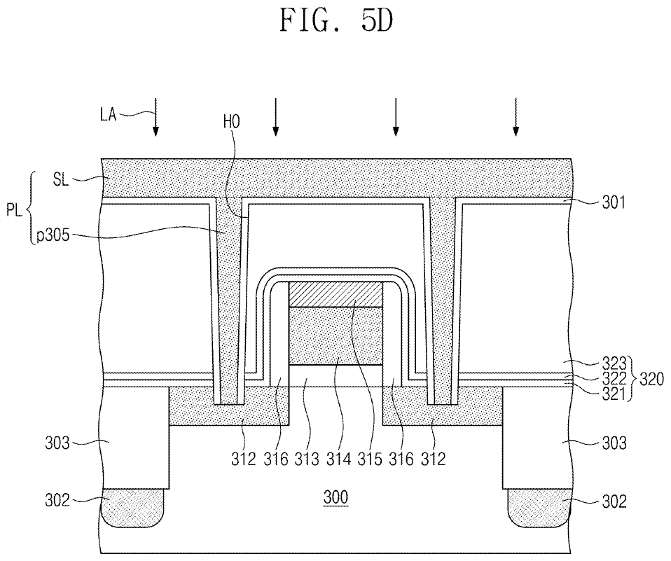

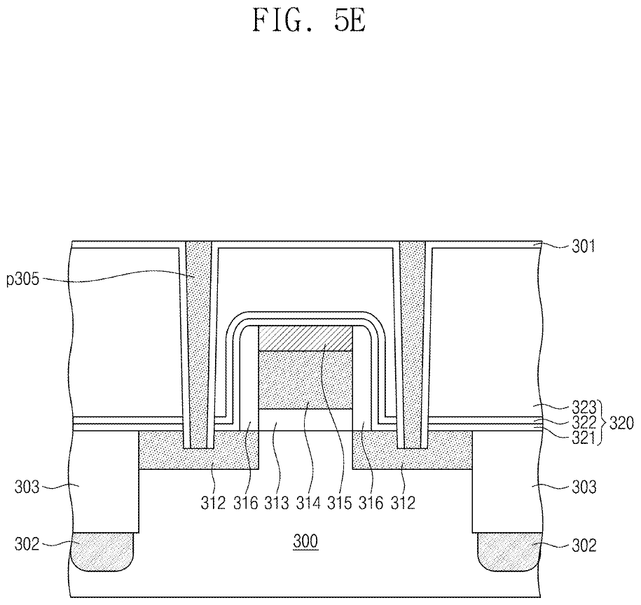

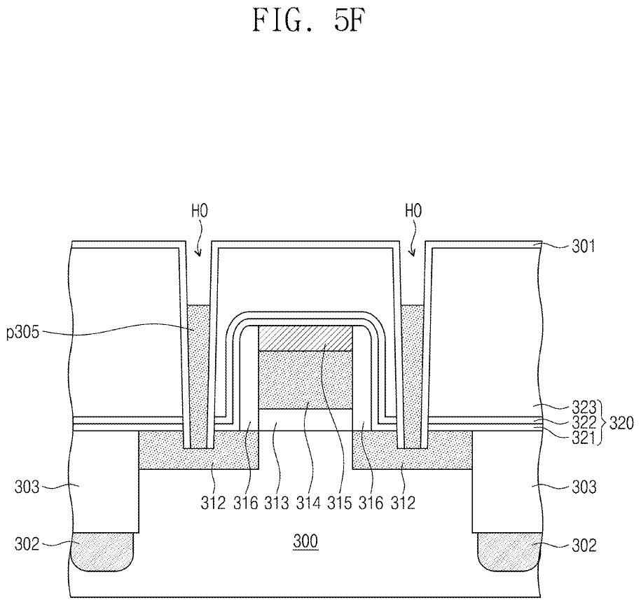

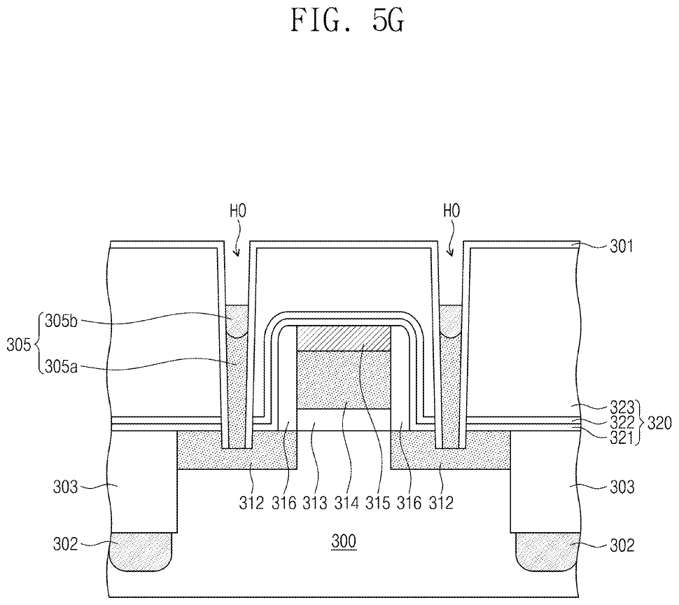

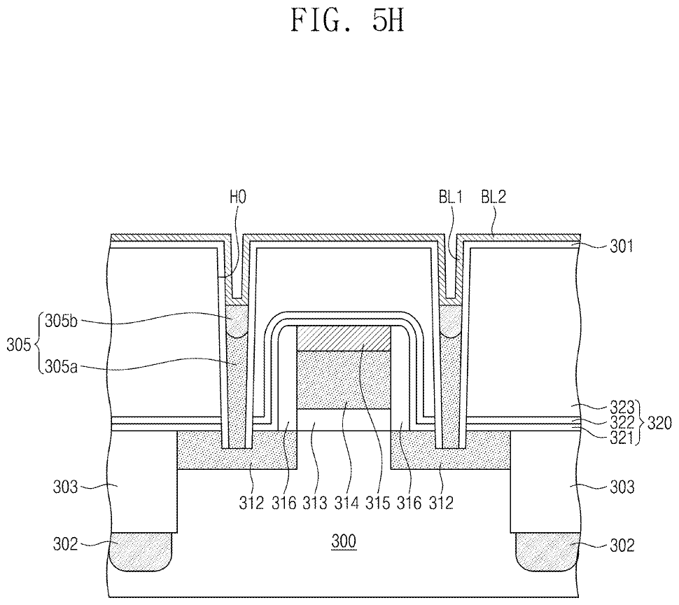

FIGS. 5A, 5B, 5C, 5D, 5E, 5F, 5G, and 5H are sectional views illustrating stages in a method of fabricating the semiconductor device of FIG. 4.

Referring to FIG. 5A, the isolation regions 302 and the device isolation layers 303 may be formed on the substrate 300. The gate insulating layer 313, the first gate conductive layer 314, and the second gate conductive layer 315 may be formed on the substrate 300. The doped regions 312 may be formed by doping the substrate 300 with impurities. The gate spacers 316 may be formed on side surfaces of the gate insulating layer 313, the first gate conductive layer 314, and the second gate conductive layer 315.

The insulating structure 320 may be formed. In an embodiment, the insulating structure 320 may be formed by sequentially forming the first insulating layer 321, the second insulating layer 322, and the third insulating layer 323.

Holes HO may be formed to penetrate the insulating structure 320. The hole HO may be overlapped with the doped region 312 in the third direction D3. The doped region 312 may be exposed to the outside through the hole HO.

Referring to FIG. 5B, the intervening layer 301 may be formed. A portion of the intervening layer 301 may be disposed in the hole HO.

Referring to FIG. 5C, a preliminary layer PL may be formed. The preliminary layer PL may include preliminary contact layers p305 and a sacrificial layer SL. The preliminary contact layer p305 may fill the hole HO. The preliminary contact layer p305 may be formed on the doped region 312. The sacrificial layer SL may be disposed on the preliminary contact layers p305. Although, for convenience in description, the sacrificial layer SL and the preliminary contact layer p305 have been described as distinct layers, the sacrificial layer SL and the preliminary contact layer p305 may be connected to each other without any interface therebetween, and the preliminary layer PL may have a single object structure.

The preliminary layer PL may be formed by depositing an impurity-doped silicon layer. The preliminary layer PL may be formed of or include amorphous silicon.

Referring to FIG. 5D, a laser annealing process may be performed. The laser annealing process may include irradiating the preliminary layer PL with a laser beam LA. As a result of the laser annealing process, at least a portion of the preliminary layer PL may be melted and solidified. The laser annealing process may lead to an increase of a mean size of crystalline grains in the preliminary layer PL. After the laser annealing process, the preliminary layer PL may include poly silicon. In an embodiment, a wavelength of the laser beam LA may be within a wavelength range of visible (e.g., green) light. In an embodiment, after the laser annealing process, the preliminary layer PL may have the same crystal direction as the doped region 312.

Referring to FIG. 5E, the sacrificial layer SL of the preliminary layer PL may be removed. In an embodiment, the sacrificial layer SL may be removed by a chemical mechanical polishing process.

Referring to FIG. 5F, an upper portion of the preliminary contact layer p305 may be etched. In an embodiment, an etch-back process may be performed to etch the upper portion of the preliminary contact layer p305. As a result of the etching of the upper portion of the preliminary contact layer p305, a top of the hole HO may be opened.

Referring to FIG. 5G, the first and second portions 305a and 305b of the contact 305 may be formed by doping the preliminary contact layer p305 with impurities. The preliminary contact layer p305 may be doped with impurities such that an impurity concentration of the second portion 305b of the contact 305 is higher than an impurity concentration of the first portion 305a of the contact 305.

Referring to FIG. 5H, the first barrier layer BL1 and the second barrier layer BL2 may be formed. Referring back to FIG. 4, the first conductive layer CL1 and the second conductive layer CL2 may be formed.

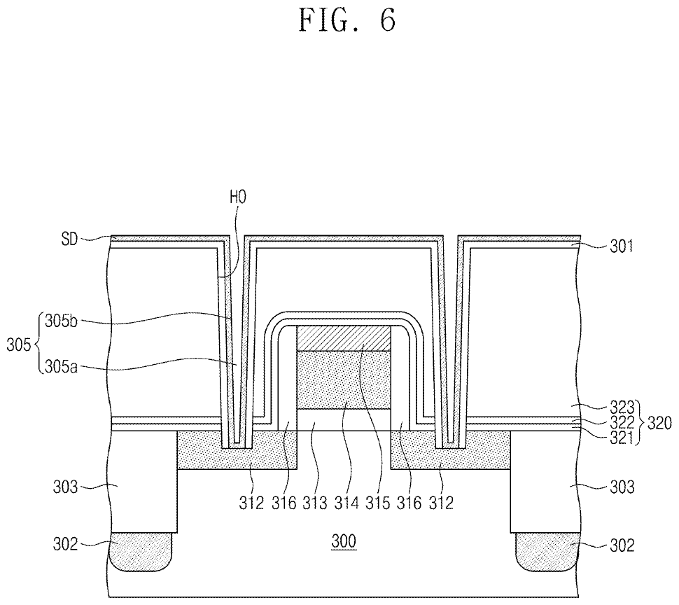

FIG. 6 is a sectional view illustrating a method of fabricating the semiconductor device of FIG. 4.

Referring to FIG. 6, a seed layer SD may be formed before the formation of the preliminary layer PL of FIG. 5C. The seed layer SD may be formed on the intervening layer 301. The seed layer SD may be in contact with the doped region 312. The preliminary layer PL of FIG. 5C may be formed using the seed layer SD as a seed. The seed layer SD may be formed of or include poly silicon. The seed layer SD may further contain at least one of carbon or nitrogen.

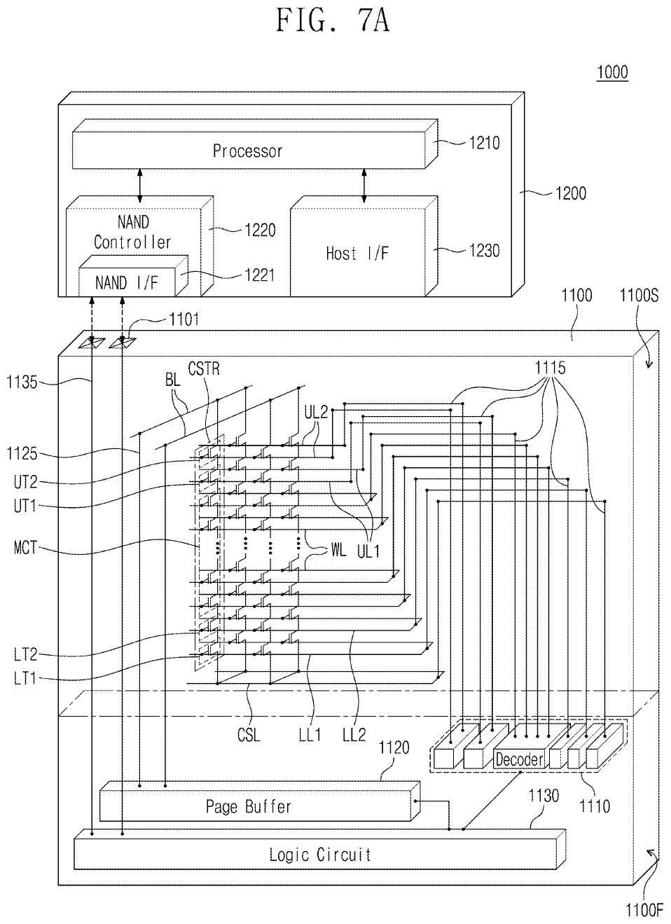

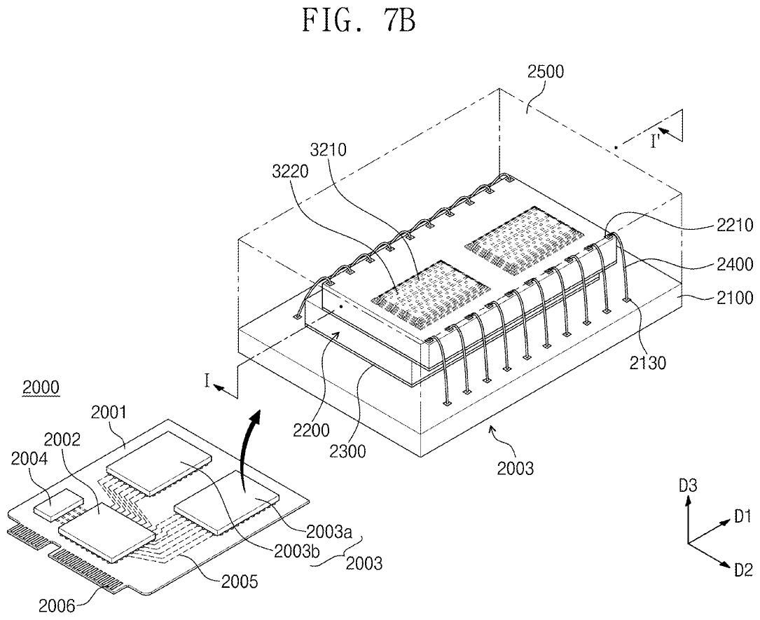

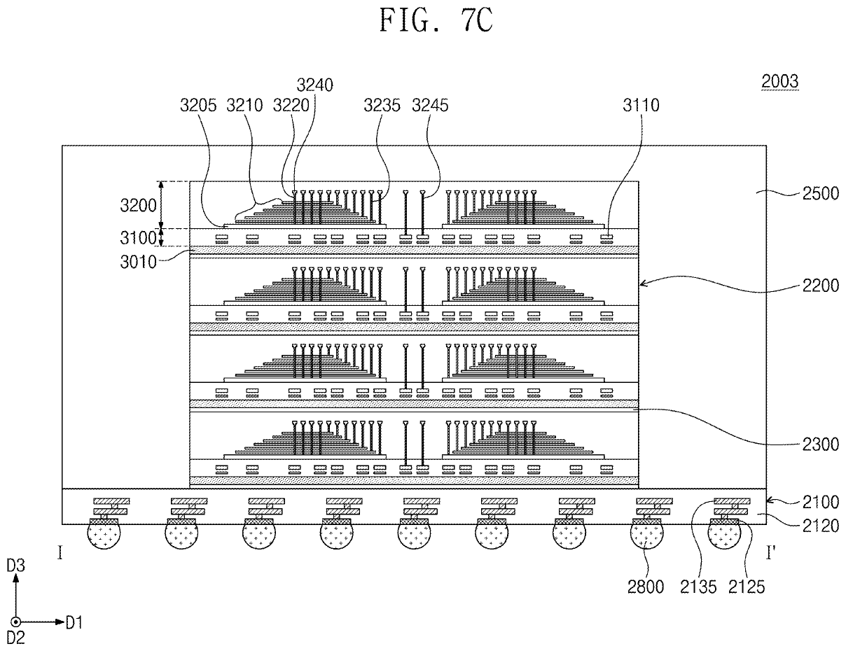

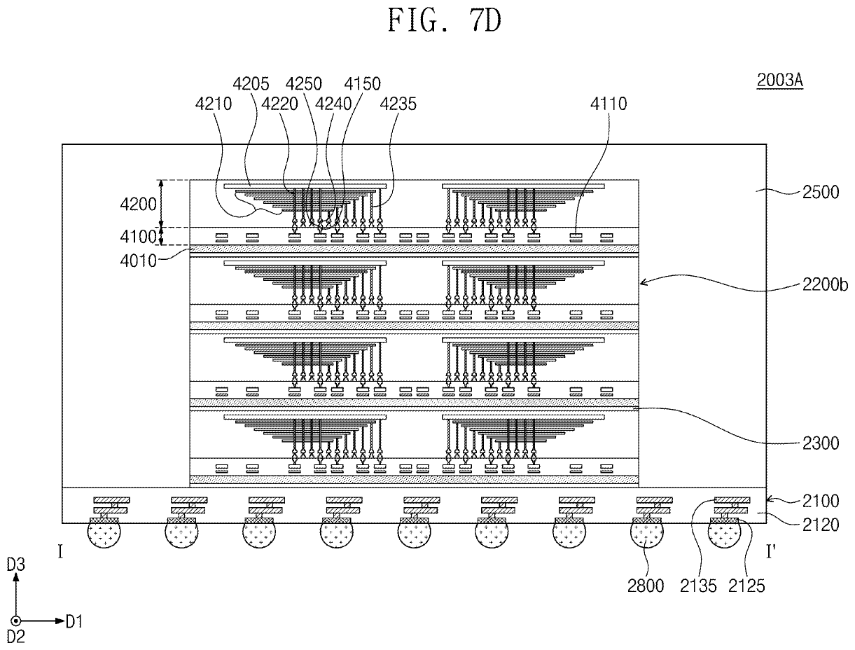

FIG. 7A is a schematic diagram illustrating an electronic system including a semiconductor device according to an embodiment.

Referring to FIG. 7A, an electronic system 1000 according to an embodiment may include a semiconductor device 1100 and a controller 1200, which is electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device and may be, e.g., a NAND FLASH memory device. The semiconductor device 1100 may include a first structure 1100F and a second structure 1100S on the first structure 1100F. In an embodiment, the first structure 1100F may be disposed beside the second structure 1100S. The first structure 1100F may be a peripheral circuit structure, which includes a decoder circuit 1110, a page buffer 1120, and a logic circuit 1130. The second structure 1100S may be a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT, which are disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include a string selection transistor, and the lower transistors LT1 and LT2 may include a ground selection transistor. The gate lower lines LL1 and LL2 may be respectively used as gate electrodes of the lower transistors LT1 and LT2. The word lines WL may be used as gate electrodes of the memory cell transistors MCT, respectively, and the gate upper lines UL1 and UL2 may be used as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may be configured to perform a control operation on at least selected one of the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1210, a NAND controller 1220, and a host interface 1230. In an embodiment, the electronic system 1000 may include a plurality of semiconductor devices 1100, and in this case, the controller 1200 may be configured to control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and receive control commands to control the semiconductor device 1100, data to be written in or read from the memory cell transistors MCT of the semiconductor device 1100, and so forth. The host interface 1230 may be configured to allow for communication between the electronic system 1000 and an external host. When a control command is received from the external host through the host interface 1230, the processor 1210 may control the semiconductor device 1100 in response to the control command.

FIG. 7B is a perspective view schematically illustrating an electronic system including a semiconductor device according to an embodiment.

Referring to FIG. 7B, an electronic system 2000 according to an embodiment may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In an embodiment, the electronic system 2000 may communicate with the external host, in accordance with one of interfaces, e.g., universal serial bus (USB), peripheral component interconnect express (PCI-Express), serial advanced technology attachment (SATA), universal flash storage (UFS) M-PHY, or the like. In an embodiment, the electronic system 2000 may be driven by an electric power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In an embodiment, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed in bottom surfaces of the semiconductor chips 2200, a connection structure 2400, which electrically connects the semiconductor chips 2200 to the package substrate 2100, and a molding layer 2500, which is provided on the package substrate 2100 to cover the semiconductor chips 2200 and the connection structure 2400.

The package substrate 2100 may be a printed circuit board, which includes package upper pads 2130. Each of the semiconductor chips 2200 may include an input/output pad 2210. The input/output pad 2210 may correspond to the input/output pad 1101 of FIG. 7A. Each of the semiconductor chips 2200 may include gate stacks 3210 and memory channel structures 3220. Each of the semiconductor chips 2200 may include a semiconductor device.

In an embodiment, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively, in each of the first and second semiconductor packages 2003a and 2003b, the semiconductor chips 2200 may be electrically connected to each other by a connection structure including through-silicon vias (TSVs), not by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on an additional interposer substrate different from the main substrate 2001 and may be connected to each other through interconnection lines, which are provided in the interposer substrate.

FIGS. 7C and 7D are sectional views, each of which schematically illustrates a semiconductor package according to an embodiment. Each of FIGS. 7C and 7D schematically illustrates an example of the semiconductor package 2003 of FIG. 7B taken along a line I-I′ of FIG. 7B.

Referring to FIG. 7C, in the semiconductor package 2003, the package substrate 2100 may be a printed circuit board. The package substrate 2100 may include a package substrate body portion 2120, package upper pads 2130 (e.g., of FIG. 7B) disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400 (e.g., of FIG. 7B). The lower pads 2125 may be connected to the interconnection patterns 2005 of the main substrate 2001 of the electronic system 2000, which is shown in FIG. 7B, through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region provided with peripheral lines 3110. The second structure 3200 may include a common source line 3205, a gate stack 3210 on the common source line 3205, the memory channel structures 3220, which are provided to penetrate the gate stack 3210, bit lines 3240, which are electrically connected to the memory channel structures 3220, and gate contact plugs 3235, which are electrically connected to the word lines WL (e.g., see FIG. 7A) of the gate stack 3210.

Each of the semiconductor chips 2200 may be electrically connected to the peripheral lines 3110 of the first structure 3100 and may include a penetration line 3245, which is extended into the second structure 3200. The penetration line 3245 may be disposed outside the gate stack 3210. In an embodiment, the penetration line 3245 may be provided to penetrate the gate stack 3210. Each of the semiconductor chips 2200 may further include the input/output pad 2210 of FIG. 7B.

Referring to FIG. 7D, in a semiconductor package 2003A, each of semiconductor chips 2200a may include a semiconductor substrate 4010, a first structure 4100 on the semiconductor substrate 4010, and a second structure 4200, which is disposed on the first structure 4100 and is bonded to the first structure 4100 by a wafer bonding method.

The first structure 4100 may include a peripheral circuit region, in which a peripheral line 4110 and first junction structures 4150 are provided. The second structure 4200 may include a common source line 4205, a gate stack 4210 between the common source line 4205 and the first structure 4100, memory channel structures 4220, which are provided to penetrate the gate stack 4210, bit lines 4240 electrically connected to the memory channel structures 4220, gate contact plugs 4235, which are electrically connected to the word lines WL of FIG. 7A of the gate stack 4210, respectively, and second junction structures 4250. For example, the second junction structures 4250 may be electrically connected to the memory channel structures 4220, respectively, through the bit lines 4240, which are electrically connected to the memory channel structures 4220. The first junction structures 4150 of the first structure 4100 and the second junction structures 4250 of the second structure 4200 may be bonded to each other. In an embodiment, the bonding portion of the first and second junction structures 4150 and 4250 may be formed of copper (Cu). Each of the semiconductor chips 2200b may further include the input/output pad 2210 of FIG. 7B.

The semiconductor chips 2200 of FIG. 7C and the semiconductor chips 2200b of FIG. 7D may be electrically connected to each other by the connection structures 2400 of FIG. 7B, which are provided in the form of bonding wires. However, in an embodiment, semiconductor chips, which are provided in the same semiconductor package as the semiconductor chips 2200 of FIG. 7C or the semiconductor chips 2200b of FIG. 7D, may be electrically connected to each other through a connection structure including the through-silicon vias (TSVs).

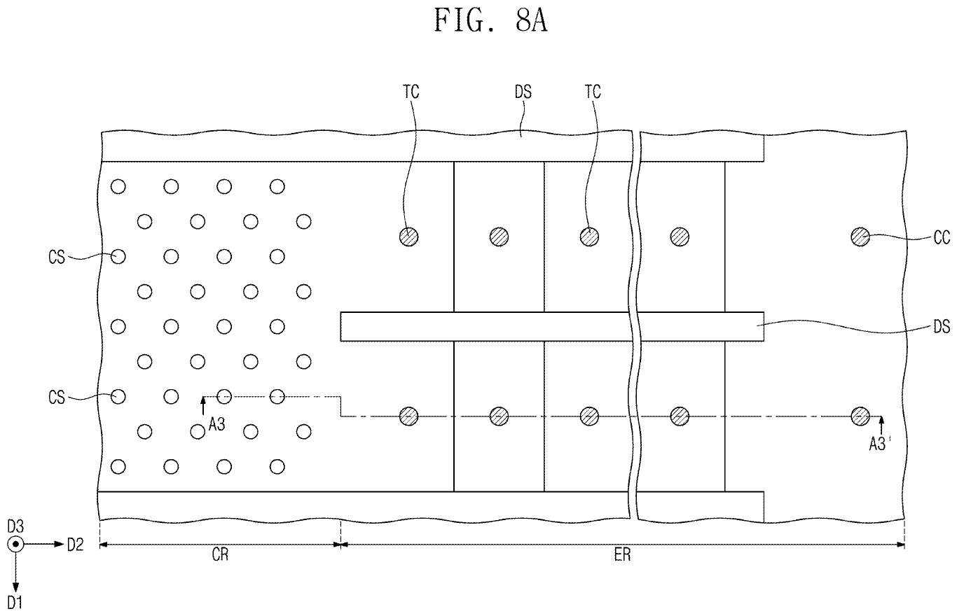

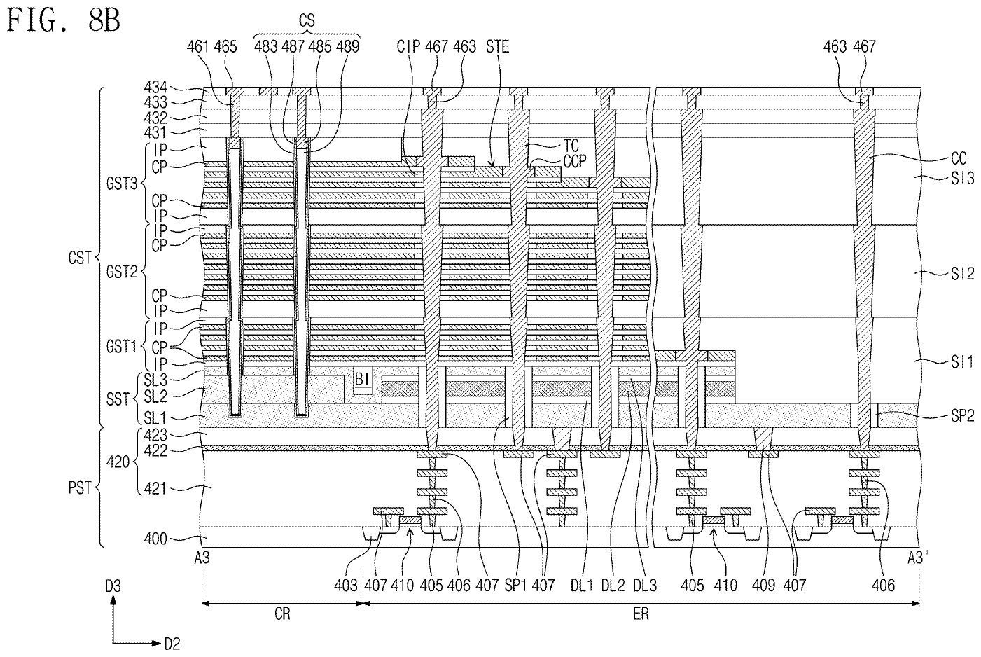

FIG. 8A is a plan view of a semiconductor device according to an embodiment. FIG. 8B is a sectional view taken along a line A3-A3′ of FIG. 8A.

Referring to FIGS. 8A and 8B, a semiconductor device may include a peripheral circuit structure PST and a memory cell structure CST on the peripheral circuit structure PST.

The peripheral circuit structure PST may include a substrate 400. The peripheral circuit structure PST may include an insulating structure 420 on the substrate 400. The insulating structure 420 may include a first insulating layer 421, a second insulating layer 422 on the first insulating layer 421, and a third insulating layer 423 on the second insulating layer 422. The first to third insulating layers 421, 422, and 423 may include at least one of insulating materials. As an example, the first and third insulating layers 421 and 423 may be formed of or include at least one of oxide materials, and the second insulating layer 422 may be formed of or include at least one of nitride materials.

In an embodiment, each of the first to third insulating layers 421, 422, and 423 may be a multiple insulating layer.

Device isolation layers 403 may be provided in the substrate 400. The peripheral circuit structure PST may further include a transistor 410. The transistor 410 may be provided between the substrate 400 and the insulating structure 420. In an embodiment, the transistor 410 may include a gate structure, a doped region, and an epitaxial pattern, similar to the transistor 110 of FIG. 1B. The epitaxial pattern of the transistor 410 may include an inclined surface connecting a top surface to a side surface.

In an embodiment, the transistor 410 may include a gate structure and a doped region, similar to the transistor 310 of FIG. 4.

The peripheral circuit structure PST may further include first contacts 405, second contacts 406, and peripheral conductive lines 407. The first contact 405 may be connected to the transistor 410. In an embodiment, the first contact 405 may include first to third portions, similar to the first contact 105 of FIG. 1B. The first and second portions of the first contact 405 may be formed of or include poly silicon. The third portion of the first contact 405 may include at least one of metallic materials. An impurity concentration of the second portion of the first contact 405 may be higher than an impurity concentration of the first portion of the first contact 405, an impurity concentration of the doped region of the transistor 410, and an impurity concentration of the epitaxial pattern of the transistor 410.

In an embodiment, the first contact 405 may include first to third portions, similar to the contact 305 of FIG. 4.

The peripheral conductive line 407 may be connected to the first contact 405 or the second contact 406. The second contact 406 may be disposed between the peripheral conductive lines 407. The first contact 405, the second contact 406, and the peripheral conductive line 407 may be provided in the first insulating layer 421 of the insulating structure 420. The second contact 406 and the peripheral conductive line 407 may include at least one of conductive materials. As an example, the second contact 406 and the peripheral conductive line 407 may include at least one of metallic materials.

The peripheral circuit structure PST may further include a source connection contact 409. The source connection contact 409 may be connected to the peripheral conductive line 407 and a first source layer SL1, which will be described below. The source connection contact 409 may be provided to penetrate the second and third insulating layers 422 and 423 of the insulating structure 420. The source connection contact 409 may include at least one of conductive materials. As an example, the source connection contact 409 may be formed of or include poly silicon.

The memory cell structure CST may include a source structure SST, a first gate stack GST1, a second gate stack GST2, a third gate stack GST3, memory channel structures CS, a first stepwise insulating layer SI1, a second stepwise insulating layer SI2, a third stepwise insulating layer SI3, a first cover insulating layer 431, a second cover insulating layer 432, a third cover insulating layer 433, a fourth cover insulating layer 434, division structures DS, third contacts 461, fourth contacts 463, bit lines 465, conductive lines 467, penetration contacts TC, and connection contacts CC.

The source structure SST may include a cell region CR and an extension region ER. The cell region CR and the extension region ER may be two separate regions, when viewed in the plan view defined by the first and second directions D1 and D2.

The source structure SST may include a first source layer SL1 provided on the peripheral circuit structure PST, a second source layer SL2 provided on the first source layer SL1, a first dummy layer DL1, a second dummy layer DL2, and a third dummy layer DL3 provided on the first source layer SL1, and a third source layer SL3 provided on the second source layer SL2 and the first to third dummy layers DL1, DL2, and DL3.

The first to third source layers SL1, SL2, and SL3 may include at least one of conductive materials. As an example, the first to third source layers SL1, SL2, and SL3 may be formed of or include poly silicon. The second source layer SL2 may be disposed in the cell region CR. The second source layer SL2 may be a common source line.

The first dummy layer DL1, the second dummy layer DL2, the third dummy layer DL3 may be sequentially provided on the first source layer SL1 in the third direction D3. The first to third dummy layers DL1, DL2, and DL3 may be disposed in the extension region ER. The first to third dummy layers DL1, DL2, and DL3 may be disposed at the same level as the second source layer SL2. The first to third dummy layers DL1, DL2, and DL3 may include at least one of insulating materials. In an embodiment, the first and third dummy layers DL1 and DL3 may be formed of or include the same insulating material, and the second dummy layer DL2 may be formed of or include an insulating material different from the first and third dummy layers DL1 and DL3. As an example, the second dummy layer DL2 may be formed of or include at least one of nitride materials, and the first and third dummy layers DL1 and DL3 may be formed of or include at least one of oxide materials.

The third source layer SL3 may cover the second source layer SL2 and the first to third dummy layers DL1, DL2, and DL3. The third source layer SL3 may be extended from the cell region CR to the extension region ER.

In an embodiment, the source structure SST may further include an insulating gapfill layer BI on the third source layer SL3. The insulating gapfill layer BI may be provided between the cell region CR and the extension region ER. The insulating gapfill layer BI may be provided between the second source layer SL2 and the first to third dummy layers DL1, DL2, and DL3. The second source layer SL2 and the first to third dummy layers DL1, DL2, and DL3 may be spaced apart from each other in the second direction D2, and the insulating gapfill layer BI and a portion of the third source layer SL3 enclosing the insulating gapfill layer BI may be provided between the second source layer SL2 and the first to third dummy layers DL1, DL2, and DL3. The insulating gapfill layer BI may include at least one of insulating materials.

The source structure SST may further include first source insulating patterns SP1 and second source insulating patterns SP2. The first and second source insulating patterns SP1 and SP2 may be disposed in the extension region ER. The first source insulating pattern SP1 may enclose the penetration contact TC. The second source insulating pattern SP2 may enclose the connection contact CC.

The first source insulating pattern SP1 may be provided to penetrate the third source layer SL3, the first to third dummy layers DL1, DL2, and DL3, and the first source layer SL1. The first source insulating pattern SP1 may be enclosed by the third source layer SL3, the first to third dummy layers DL1, DL2, and DL3, and the first source layer SL1. The second source insulating pattern SP2 may be provided to penetrate the first source layer SL1. The second source insulating pattern SP2 may be enclosed by the first source layer SL1. The first and second source insulating patterns SP1 and SP2 may include at least one of insulating materials. As an example, the first and second source insulating patterns SP1 and SP2 may be formed of or include at least one of oxide materials.

The first gate stack GST1 may be provided on the source structure SST. The second gate stack GST2 may be provided on the first gate stack GST1. The third gate stack GST3 may be provided on the second gate stack GST2. The number of the gate stacks GST1, GST2, and GST3 may not be limited to the illustrated example. In an embodiment, the number of the gate stacks GST1, GST2, and GST3 may be equal to or less than 2 or may be equal to or greater than 4.

Each of the first to third gate stacks GST1, GST2, and GST3 may include insulating patterns IP and conductive patterns CP, which are alternately stacked on top of each other in the third direction D3. A staircase structure STE may be defined by the insulating patterns IP and the conductive patterns CP.

The insulating patterns IP may include at least one of insulating materials. As an example, the insulating patterns IP may be formed of or include at least one of oxide materials. The conductive patterns CP may include at least one of conductive materials. As an example, the conductive patterns CP may be formed of or include tungsten.

Each of the first to third gate stacks GST1, GST2, and GST3 may further include contact insulating patterns CIP. The contact insulating pattern CIP may be disposed at the same level as the conductive pattern CP. The contact insulating pattern CIP may enclose the penetration contact TC. The contact insulating pattern CIP may be disposed between the penetration contact TC and the conductive pattern CP. The contact insulating pattern CIP may include at least one of insulating materials. As an example, the contact insulating pattern CIP may be formed of or include at least one of oxide materials.

The first stepwise insulating layer SI1 may be provided on the source structure SST. The first stepwise insulating layer SI1 may be disposed at the same level as the first gate stack GST1. The second stepwise insulating layer SI2 may be provided on the first stepwise insulating layer SI1. The second stepwise insulating layer SI2 may be disposed at the same level as the second gate stack GST2. The third stepwise insulating layer SI3 may be provided on the second stepwise insulating layer SI2. The third stepwise insulating layer SI3 may be disposed at the same level as the third gate stack GST3. The first to third stepwise insulating layers SI1, SI2, and SI3 may include at least one of insulating materials. As an example, the first to third stepwise insulating layers SI1, SI2, and SI3 may be formed of or include at least one of oxide materials.

The memory channel structures CS may be extended in the third direction D3 to penetrate the first gate stack GST1, the second gate stack GST2, the third gate stack GST3, the third source layer SL3, and the second source layer SL2. Each of the memory channel structures CS may include an insulating capping layer 489, a channel layer 487 enclosing the insulating capping layer 489, and a memory layer 483 enclosing the channel layer 487.

The insulating capping layer 489 may include at least one of insulating materials. As an example, the insulating capping layer 489 may be formed of or include at least one of oxide materials. The channel layer 487 may include at least one of conductive materials. As an example, the channel layer 487 may be formed of or include poly silicon. The channel layer 487 may be electrically connected to the second source layer SL2. The second source layer SL2 may penetrate the memory layer 483 and may be connected to the channel layer 487.

The memory layer 483 may be configured to store data. In an embodiment, the memory layer 483 may include a tunnel insulating layer enclosing the channel layer 487, a data storing layer enclosing the tunnel insulating layer, and a blocking layer enclosing the data storing layer.

Each of the memory channel structures CS may further include a bit line pad 485 provided on the channel layer 487. The bit line pad 485 may include at least one of conductive materials. As an example, the bit line pad 485 may be formed of or include at least one of poly silicon or metallic materials.

The first cover insulating layer 431 may be provided on the third gate stack GST3, the third stepwise insulating layer SI3, and the memory channel structures CS. The first cover insulating layer 431 may include at least one of insulating materials.

The second cover insulating layer 432 may be provided on the first cover insulating layer 431. The second cover insulating layer 432 may include at least one of insulating materials.

The penetration contacts TC may be extended in the third direction D3. The penetration contact TC may be provided to penetrate the second cover insulating layer 432, the first cover insulating layer 431, at least one of the first stepwise insulating layer SI1 and the first gate stack GST1, at least one of the second stepwise insulating layer SI2 and the second gate stack GST2, at least one of the third stepwise insulating layer SI3 and the third gate stack GST3, the third source layer SL3, the third dummy layer DL3, the second dummy layer DL2, the first dummy layer DL1, the first source layer SL1, the first source insulating pattern SP1, the third insulating layer 423, and the second insulating layer 422. The penetration contact TC may be connected to the peripheral conductive line 407. The penetration contact TC may include a contact connecting portion CCP connected to the conductive pattern CP. The penetration contact TC may include at least one of conductive materials.

The connection contacts CC may be extended in the third direction D3. The connection contact CC may be provided to penetrate the second cover insulating layer 432, the first cover insulating layer 431, the first stepwise insulating layer SI1, the second stepwise insulating layer SI2, the third stepwise insulating layer SI3, the first source layer SL1, the second source insulating pattern SP2, the third insulating layer 423, and the second insulating layer 422. The connection contact CC may be connected to the peripheral conductive line 407.

The third cover insulating layer 433 may be provided on the second cover insulating layer 432, the penetration contacts TC, and the connection contacts CC. The fourth cover insulating layer 434 may be provided on the third cover insulating layer 433. The third and fourth cover insulating layers 433 and 434 may include at least one of insulating materials.

The division structures DS may be provided to penetrate the first to third gate stacks GST1, GST2, and GST3. The division structures DS may be extended in the second direction D2. The division structure DS may include at least one of insulating materials. In an embodiment, the division structure DS may include at least one of conductive materials.

The third contact 461 may be connected to the memory channel structure CS. The third contact 461 may be provided to penetrate the first to third cover insulating layers 431, 432, and 433. The fourth contact 463 may be connected to the penetration contact TC or the connection contact CC. The fourth contact 463 may be provided to penetrate the third cover insulating layer 433. The bit line 465 may be connected to the third contact 461. The bit line 465 may be disposed in the fourth cover insulating layer 434. The bit line 465 may be extended in the first direction D1. The conductive line 467 may be connected to the fourth contact 463. The conductive line 467 may be disposed in the fourth cover insulating layer 434. The third contact 461, the fourth contact 463, the bit line 465, and the conductive line 467 may include at least one of conductive materials.

In a semiconductor device according to an embodiment, a current path between a metal-containing portion of a contact and a gate structure may be relatively long. Thus, a doped region may have a relatively small size, and an integration density of the semiconductor device may be increased.

In a semiconductor device according to an embodiment, the doped region may have a relatively small thickness. Thus, a distance between an isolation region and the doped region may be relatively large, and it may be possible to realize a semiconductor device with a relatively high breakdown voltage.

An embodiment provides a semiconductor device with improved electrical and reliability characteristics and an electronic system including the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
a doped region on the substrate, the doped region including impurities of a first conductivity type at a first concentration;
a gate structure on the substrate; and
a first contact electrically connected to the doped region, the first contact including a first portion, a second portion on the first portion, and a third portion on the second portion, the first portion and the second portion including poly silicon, the third portion including at least one metallic material, and the second portion including impurities of the first conductivity type at a second concentration higher than the first concentration.

2. The semiconductor device as claimed in claim 1, further comprising an epitaxial pattern between the first contact and the doped region, the first portion of the first contact being in contact with a top surface of the epitaxial pattern.

3. The semiconductor device as claimed in claim 2, wherein the epitaxial pattern includes a first inclined surface and a second inclined surface, which are connected to the top surface of the epitaxial pattern.

4. The semiconductor device as claimed in claim 3, wherein the epitaxial pattern further includes a side surface connected to the first inclined surface, the side surface of the epitaxial pattern being in contact with a side surface of the gate structure.

5. The semiconductor device as claimed in claim 2, wherein the epitaxial pattern includes a single crystalline silicon and impurities of the first conductivity type at a third concentration, the third concentration being lower than the second concentration.

6. The semiconductor device as claimed in claim 1, wherein the first portion of the first contact does not contain an impurity.

7. The semiconductor device as claimed in claim 1, wherein the gate structure includes:
a gate insulating layer;
a first gate conductive layer on the gate insulating layer;
a second gate conductive layer on the first gate conductive layer, a level of a top surface of the second portion of the first contact being higher than a level of a top surface of the second gate conductive layer; and
a gate spacer on side surfaces of the gate insulating layer, the first gate conductive layer, and the second gate conductive layer.

8. The semiconductor device as claimed in claim 7, further comprising a second contact in contact with the second gate conductive layer, the second contact including at least one metallic material.

9. The semiconductor device as claimed in claim 7, further comprising an insulating structure covering the gate structure, the insulating structure being in contact with the top surface of the second gate conductive layer.

10. A semiconductor device, comprising:
a substrate;
a doped region on the substrate;
a gate structure on the substrate;
an epitaxial pattern on the doped region the epitaxial pattern including a first inclined surface, a second inclined surface, a top surface between the first inclined surface and the second inclined surface, a first side surface connected to the first inclined surface, and a second side surface connected to the second inclined surface; and
a contact on the epitaxial pattern, the first side surface of the epitaxial pattern being in contact with a side surface of the gate structure.

11. The semiconductor device as claimed in claim 10, wherein the first side surface and the second side surface of the epitaxial pattern are parallel to the side surface of the gate structure.

12. The semiconductor device as claimed in claim 10, wherein the gate structure includes:
a gate insulating layer;
a first gate conductive layer on the gate insulating layer;
a second gate conductive layer on the first gate conductive layer; and
a gate spacer on side surfaces of the gate insulating layer, the first gate conductive layer, and the second gate conductive layer,
wherein the top surface of the epitaxial pattern is at a level higher than a top surface of the gate insulating layer and lower than a top surface of the first gate conductive layer.

13. The semiconductor device as claimed in claim 10, wherein:
the contact includes a first portion on the epitaxial pattern, a second portion on the first portion, and a third portion on the second portion,
the first portion and the second portion of the contact include poly silicon, and
the third portion of the contact includes at least one metallic material.

14. The semiconductor device as claimed in claim 13, wherein:
the epitaxial pattern includes impurities of a first conductivity type at a first concentration,
the second portion of the contact includes impurities of the first conductivity type at a second concentration, and
the first concentration is lower than the second concentration.

15. The semiconductor device as claimed in claim 14, wherein the first portion of the contact includes impurities of the first conductivity type at a third concentration, the third concentration being lower than the second concentration.

16. The semiconductor device as claimed in claim 13, wherein the third portion of the contact includes a barrier layer on the second portion and a conductive layer on the barrier layer.

17. The semiconductor device as claimed in claim 13, wherein a level of a bottom surface of the first portion of the contact is higher than a level of a bottom surface of the doped region and is lower than a level of a top surface of the doped region.

18. The semiconductor device as claimed in claim 10, wherein a width of the contact is smaller than a width of the epitaxial pattern.

19. A semiconductor device, comprising:
a substrate;
an isolation region on the substrate, the isolation region including impurities;
a device isolation layer on the isolation region;
a doped region on the substrate, the doped region including impurities of a first conductivity type, the impurities of the doped region being of a different conductivity than the impurities of the isolation region;
a gate structure on the substrate;
an insulating structure covering the gate structure; and
a contact electrically connected to the doped region, the contact including a first portion, a second portion on the first portion, and a third portion on the second portion, the first portion and the second portion including poly silicon, the third portion including at least one metallic material, and the second portion including impurities of the first conductivity type.

20. The semiconductor device as claimed in claim 19, wherein a level of a top surface of the second portion of the contact is higher than a level of a top surface of the gate structure.
